(19) United States
(12) Patent Application Publication
(10) Pub. No.: US 2005/0151443 A1
(43) Pub. Date: Jul. 14, 2005

(54) Piezoelectric micro positioner for large temperature range

(75) Inventors: Charles E. Seeley, Niskayuna, NY (US); Matthew C. Nielsen, Scotia, NY (US); Jeffrey B. Fortin, Niskuyuna, NY (US)

Correspondence Address: Leopold Presser;Scully, Scott, Murphy & Presser, 400 Garden City Plaza, Garden City, NY, 11530, US

(73) Assignee: Lockheed Martin Corporation, Bethesda, MD (US)

(21) Appl. No.: 11/014,282

(22) Filed: Dec. 16, 2004

Related U.S. Application Data
(63) Continuation-in-part of application No. 10/277,064, filed on Oct. 21, 2002.

(51) Int. Cl. H02N 2/00; H01L 41/04

(52) U.S. Cl. 310/313 B

(57) ABSTRACT

Disclosed are a piezoelectric actuator operable over a temperature range, and a method of operating a piezoelectric actuator. The piezoelectric actuator, generally, comprises a support structure, a piezoelectric material supported by the support structure, and an insert disposed between the support structure and the piezoelectric material. The piezoelectric material and the insert are positioned in series, the piezoelectric material and the insert each have a respective length, and together the piezoelectric material and the insert have a combined length. The length of the piezoelectric material changes in response to a voltage applied to the piezoelectric material. Also, the respective lengths of the piezoelectric material and the insert change, in opposite directions, in response to the same change in temperature, and, in this way, the insert mitigates changes in the combined length of the insert and the piezoelectric material due to temperature changes.

### CROSS REFERENCE TO RELATED APPLICATIONS

This application is a continuation-in-part of Application No. 10/277,064, filed Oct. 21, 2002.

### BACKGROUND OF THE INVENTION

1. Field of the Invention

This invention generally relates to micropositioning devices; and more specifically, the invention relates to piezoelectric micro positioning devices.

2. Background Art

There is generally a need for micropositioning devices; and for example, these devices may be used in jet and rocket propulsion engines to control valves for air and fuel flow. Micropositioning devices are often made of piezoelectric materials because, under the right conditions, these materials expand and contract in very small amounts in a precise, controlled manner using an electrical input. Piezoelectric materials, however, are very sensitive to temperature changes, which also cause contraction or expansion due to thermal effects. In fact, a significant temperature change may cause a piezoelectric micropositioning device to expand or contract such that it is completely outside the specification limits of its intended operation.

For example, piezoelectric stack actuators are often used as micro positioning devices. The electromechanical coupling of the piezoelectric material causes the actuator to increase its length when a voltage is applied. The range, or specification limits, of the displacement caused by the change in length is an important design consideration. The actuator also changes length as a result of thermal expansion, and the undesirable change in length due to thermal expansion may significantly impair the ability of the actuator to operate within its specification limits.

Problems introduced by thermal expansion have resulted in strict operating limits on piezoelectric micro positioning devices. This is an important factor that has prevented the development of high temperature piezoelectric micro positioners.

### SUMMARY OF THE INVENTION

An object of this invention is to improve piezoelectric micro-actuators.

Another object of the present invention is to use piezoelectric devices as micro actuators/positioners over a wide temperature range.

A further object of the invention is to cancel out the effects of thermal expansion, in a piezoelectric micro-actuator, that would cause the micro positioner to not meet the specification limits of the displacement it generates.

These and other objectives are attained with a piezoelectric actuator operable over a temperature range, and a method of operating a piezoelectric actuator. The piezoelectric actuator, generally, comprises a support structure, a piezoelectric material held in place by the support structure, and an insert disposed between the support member and the piezoelectric material. The piezoelectric material and the insert are positioned in series, the piezoelectric material and the insert each have a respective length, and together the piezoelectric material and the insert have a combined length.

The length of the piezoelectric material changes in response to a voltage applied to the piezoelectric material. Also, the respective lengths of the piezoelectric material and the insert change, in opposite directions, in response to the same change in temperature, and, in this way, the insert mitigates changes in the combined length of the insert and the piezoelectric material due to temperature changes.

The piezoelectric material has a negative coefficient of thermal expansion and contracts in response to increased temperature over the range of operational temperature. The insert has a positive coefficient of thermal expansion and expands in response to increased temperature. Preferably, over a given temperature range, changes in the length of the insert due to temperature changes are substantially equal in magnitude and opposite in direction to changes in the length of the piezoelectric material due to the same temperature changes, so that these temperature changes do not substantially change the combined length of the insert and the piezoelectric material. For example, the magnitude of the coefficient of thermal expansion of the insert may be at least ten times the magnitude of the coefficient of thermal expansion of the piezoelectric material.

Further benefits and advantages of the invention will become apparent from a consideration of the following detailed description, given with reference to the accompanying drawing, which specifies and shows preferred embodiments of the invention.

### BRIEF DESCRIPTION OF THE DRAWINGS

FIG. 1 shows a piezoelectric actuator embodying the present invention.

FIG. 2 illustrates the operation of the actuator of FIG. 1, without the insert, after various temperature changes.

FIG. 3 illustrates the operation of the actuator of FIG. 1, with the insert, after the same temperature changes.

### DETAILED DESCRIPTION OF THE PREFERRED EMBODIMENTS

Piezoelectric stack actuators are often used as micro positioning devices. The electro-mechanical coupling of the piezoelectric material causes the actuator to increase its length when a voltage is applied, and the range, or specification limits, of the displacement caused by the change in length is an important design consideration. The actuator also changes length as a result of thermal expansion, and this undesirable change in length due to thermal expansion may significantly impair the ability of the actuator to operate within its specification limits.

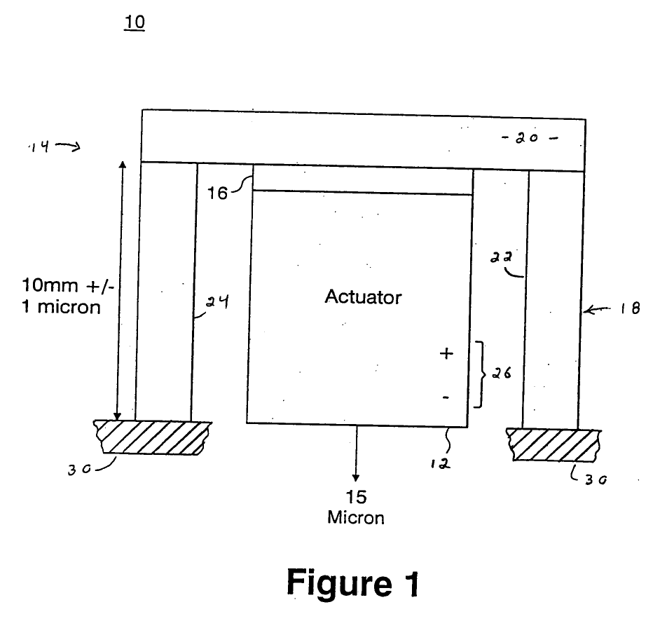

In accordance with the present invention, this undesirable shrinkage is counter-acted by another material that expands when heated and that is placed in series with the piezoelectric actuator. The net effect is that the actuator operates within its specification limits over a wide range of temperatures. FIG. 1 shows an actuator 10 embodying the present invention. Generally, actuator 10 comprises piezoelectric material actuator 12, supports means 14 and insert 16. Preferably support means 14 includes outside support structure 18 and truss structure 20, and support structure 18, in term, preferably includes support legs 22 and 24. Piezoelectric material 12 is secured to supports means 14 with insert 16 located in series between the piezoelectric material and the support means.

In use, an electric voltage, represented at 26 is applied to the material 12, causing that material to expand. This expansion may be used, in any suitable way, to control or actuate some other mechanism. For example, the actuator may be used to change gradually the position of a control valve, or the actuator may be used as a switch to turn a control or guide mechanism on or off.

Thus, piezoelectric material 12 changes its length in proportion to the applied voltage, which is a desirable effect. However, material 12 also changes its length in proportion to changes in temperature, which, generally, is an undesirable effect. In particular, piezoelectric material 12 has a negative coefficient of thermal expansion (CTE), and therefore it shrinks when heated. Insert 16 is selected to have a positive CTE, and preferably the CTE of insert 16 is much larger in magnitude than the CTE of piezoelectric material 12.

The combination of the thermal expansion and contraction, respectively, of the insert 16 and piezoelectric material 12 results in a net change in the combined length of insert 16 and material 12 of approximately zero over a wide range of temperatures. Since the magnitude of the CTE of the insert 16 can be selected to be much larger than the magnitude of the CTE of piezoelectric material 12, the dimension of the insert 16 can be much smaller than the dimension of material 12.

In the preferred embodiment of the invention, as mentioned above, support means 14 includes support legs 22 and 24 and truss structure 20. Legs 22 and 24 are connected to a fixed base structure 30 and extend upward therefrom, and truss structure 20 is connected to and laterally extends between the tops of legs 22 and 24. Insert 16 is connected to an underside of truss structure 20, and piezoelectric material 12 is connected to and extends downward from the insert. Both the insert 16 and the piezoelectric material 12 are located between, or inside of, legs 22 and 24, and the insert and the piezoelectric material are positioned substantially completely inside of support means 14. It should be noted that other types of support structure 18 may be used in the practice of this invention. For example, the support structure 18 may comprise a cylindrical shell, a rectangular shell, or a hollow tube.

With the above-described arrangement, piezo material 12 is connected to the support means 14, via insert 16, and this insert is located in series between the piezo material and the support means. Also, preferably, the insert 16 is made from a non-piezoelectric material, so that the thickness of the insert is independent of the voltage applied to the piezoelectric material. In addition, as shown in FIG. 1, the longitudinal axis of the piezoelectric material is collinear with the central axis of the insert, and both the piezoelectric material and the insert are generally centered between legs 20 and 22. Further, as an example, the length of the piezoelectric material may be about 19 mm, and the thickness of the insert may be about 2 mm, so that the combined length of the insert and the piezoelectric material is about 21 mm.

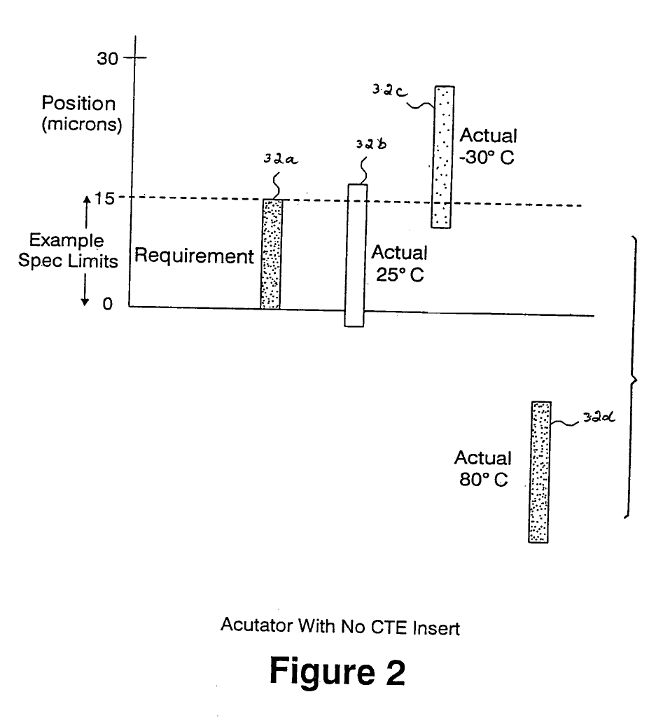

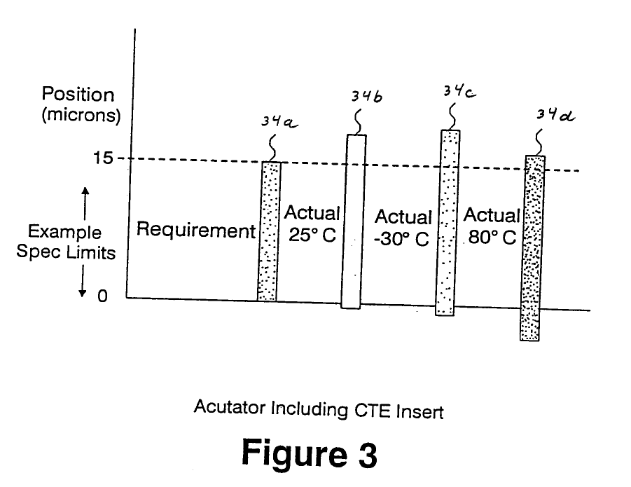

The improvement achieved with the present invention can be seen by comparing FIGS. 2 and 3, which illustrate the operation of actuator 10 without and with insert 16 respectively. In these Figures, the bars at 32a and 34a represent the specification requirement for the range of expansion of piezoelectric material 14 due to a given applied voltage, and as measured from a fixed zero point. In this illustration, that range is approximately 15 μm from that zero point.

Bars 32b, 32c and 32d of FIG. 2 show the range of movement of the piezoelectric material 12, as measured from that same zero point and for a defined applied voltage, when the temperature of the piezo material is, respectively, increased by 25° C., decreased by 30° C., and increased by 80° C. As can be seen, the range of expansion of the piezoelectric material at 32c is substantially outside the specification limits, and the range of expansion at 32d is far outside that limit.

The use of insert 16 significantly improves the performance of the actuator. With reference to FIG. 3, for the defined applied voltage, when the temperature of the piezoelectric material is increased by 25° C., decreased by 30° C., and increased by 80° C., the expansion of the piezoelectric material, as measured from the zero point, are shown, respectively, at 34b, 34c and 34d. All of these expansion ranges are substantially within the specification limits.

While it is apparent that the invention herein disclosed is well calculated to fulfill the objects stated above, it will be appreciated that numerous modifications and embodiments may be devised by those skilled in the art, and it is intended that the appended claims cover all such modifications and embodiments as fall within the true spirit and scope of the present invention.

1. A piezoelectric actuator operable over a temperature range, the actuator comprising:
a support means including:
i) a fixed base structure;
ii) an outside support structure connected to and extending upward from the fixed base structure;
iii) a truss structure connected to, supported by, and extending across a top end of said outside support structure;
a piezoelectric material supported by the truss structure and extending downward, inside said outside support structure; and
an insert disposed in series between the truss structure and the piezoelectric material;
wherein the piezoelectric material and the insert each have a respective length, and together the piezoelectric material and the insert have a combined length;
wherein the length of the piezoelectric material changes in response to a voltage applied to the piezoelectric material; and
wherein the respective lengths of the piezoelectric material and the insert change, in opposite directions, in response to the same change in temperature, whereby the insert mitigates changes in said combined length due to temperature changes.

2. A piezoelectric actuator according to claim 1, wherein:
said outside support structure includes a pair of laterally spaced apart legs connected to and extending upward from the fixed base structure;
the truss structure is connected to, is supported by, and extends across top ends of said legs; and
the piezoelectric material extends downward, between said pair of legs.

3. A piezoelectric actuator according to claim 1, wherein:
the insert is connected to an underside of the truss structure;
the piezoelectric material is connected to and extends downward from the insert; and
the insert and the piezoelectric material are substantially centered between said pair of legs.

4. A piezoelectric actuator according to claim 3, wherein:
the insert longitudinally extends downward from the truss structure;
the piezoelectric material longitudinally extends downward from the insert; and
only a single insert is disposed between the truss structure and the piezoelectric material.

5. A piezoelectric actuator according to claim 1, wherein:
the piezoelectric material has a negative coefficient of thermal expansion and contracts in response to increased temperature over the operating temperature; and
the insert has a positive coefficient of thermal expansion and expands in response to increased temperature.

6. A piezoelectric actuator according to claim 5, wherein the magnitude of the coefficient of thermal expansion of the insert is at least two times the magnitude of the coefficient of thermal expansion of the piezoelectric material.

7. A piezoelectric actuator according to claim 1, wherein:
over a given temperature range, changes in the length of the insert due to temperature changes are substantially equal in magnitude and opposite in direction to changes in the length of the piezoelectric material due to the same temperature changes, whereby said temperature changes do not substantially change the position of a distal end of the piezoelectric material.

8. A piezoelectric actuator according to claim 7, wherein said temperature range is above 25° C.

9. A piezoelectric actuator according to claim 1, wherein the combined length of the insert and the piezoelectric material is less than 100 mm.

10. A piezoelectric actuator according to claim 9, wherein the piezoelectric material has a length about nine times the length of the insert; and the combined length of the insert and the piezoelectric material is approximately 20 mm.

11. A method of operating a piezoelectric actuator of the type having a support means and an expandable piezoelectric material supported by said support structure,
wherein the support means includes:
i) a fixed base structure,
ii) an outside support structure connected to and extending upward from the fixed base structure; and
iii) a truss structure connected to, supported by, and extending across a top end of said outside support structure;
the method comprising the steps of:
supporting the piezoelectric material from the truss structure, inside said support structure;
positioning an insert in series between the truss structure and the piezoelectric material;
positioning the actuator in an environment where the temperature changes; and in response to changes in the temperature in said environment,
i) allowing the piezoelectric material to change its length; and
ii) using a change in the length of the insert to off-set changes in the length of the piezoelectric material.

12. A method according to claim 11, wherein:
the outside support structure includes a pair of laterally spaced apart legs connected to and extending upward from the fixed base structure;
the truss structure is connected to, is supported by, and extends across top ends of said legs;
the insert is connected to an underside of the truss structure;
the piezoelectric material is connected to and extends downward from the insert; and
the insert and the piezoelectric material are substantially centered between said pair of legs.

13. A method according to claim 11, wherein said environment has a temperature above 25° C.

14. A method according to claim 13, wherein said environment has a temperature above 100° C.

15. A method according to claim 11, wherein:
the piezoelectric material has a negative coefficient of thermal expansion and contracts when heated; and
the insert has a positive coefficient of thermal expansion and expands when heated.

16. A method according to claim 15, wherein the magnitude of the coefficient of thermal expansion of the insert is at least two times the magnitude of the coefficient of thermal expansion of the piezoelectric material.

17. A method according to claim 11, wherein:
the insert and the piezoelectric material have a combined length; and
the using step includes the step of using the change in the length of the insert to off-set substantially completely changes in the length of the piezoelectric material due to changes in the temperature in said environment, whereby said temperature changes do not substantially change the combined length of the insert and the piezoelectric material.

18. A method according to claim 17, wherein the combined length of the insert and the piezoelectric material is less than 100 mm.

19. A method according to claim 18, wherein the combined lengths of the insert and the piezoelectric material is approximately 20 mm.
